(19) United States
(12) Patent Application Publication
(10) Pub. No.: US 2003/0235225 A1
(43) Pub. Date: Dec. 25, 2003

(54) Guided self-aligned laser structure with integral current blocking layer

(76) Inventors: Rick Glew, Manotick (CA); Benoit Reid, Gloucester (CA)

Correspondence Address: LAHIVE & COCKFIELD, 28 STATE STREET, BOSTON, MA, 02109, US

(21) Appl. No.: 10/262,763

(22) Filed: Oct. 2, 2002

Related U.S. Application Data
(60) Provisional application No. 60/390,882, filed on Jun. 22, 2002.

(51) Int. Cl. H01S 5/00

(52) U.S. Cl. 372/46

(57) ABSTRACT

A self-aligned laser structure with an integral active and guiding layer is disclosed. It is comprised of a continuous active region and a current blocking region forming a lateral waveguide. The blocking region has an index of refraction n1 and a continuous guiding layer has an index of refraction n2, wherein n2 is greater than n1. The guiding layer and the blocking region is made of the same material. The blocking region has a real refractive index step to form a transverse optical mode, wherein the transverse laser mode is controlled by a change in doping level of the blocking region.

This is a continuation-in-part of application Ser. No. . . . filed Jun. 21, 2002. (15399JD)

### FIELD OF THE INVENTION

This invention relates to high power semiconductor diode laser structures but more particularly to a high power laser structure with a continuous active region and p-n-p blocking layers.

### BACKGROUND OF THE INVENTION

Numerous semiconductor laser structure designs have been tried.

The two most common designs are the ridge laser and the buried heterostructure. Despite the simplicity of the ridge structure, the control of the lateral optical mode is complex. In the ridge structure design, both the air/semiconductor/air refractive index step in the lateral direction and the stress in the dielectric layers and the metal contacts contribute to the effective shape of the lateral optical mode. The advantages of this design are that only one growth step is required (two steps if a grating is included), the active region is continuous and the processing is simple which usually leads to a high yield process. Generally, the disadvantages are that the threshold current is high because lateral leakage current is important, and the requirement for large contact area for improved power handling capability leads to high beam ellipticity which degrades fiber coupling efficiency in some coupling schemes. The main cause for these drawbacks are that lateral current and optical confinement cannot be separated from one another. In wide ridge structures the mode control for single lateral mode operation is more difficult to obtain than in narrow ridge structures. The reason is that wide ridges require a relatively large distance of the air-semiconductor interface from the core of the waveguide for weak optical guiding making the device more sensitive to parasitic effects like current spreading and manufacturing induced strain.

In the p-n-blocking buried heterostructure, the lateral optical waveguide is fabricated by etching away part of the active layer. Subsequently the structure is overgrown. The advantages of this structure are that the threshold current is low because the lateral leakage current is low, the lateral mode control is good, and the contact area can be made large independently of the waveguide structure giving good heat dissipation. The disadvantages are that the structure requires three growth steps (four steps if a grating is included) that lower the yield and since the active region has been etched, the non-radiative recombination can increase significantly and can degrade the device performance and its reliability. Also, the high doping levels in the p-n current blocking layers are located in areas where the optical intensity is high resulting in increased optical losses, which prevent the use of long cavities usually necessary to achieve high power.

It would then be very attractive if the simplicity and high yield of the ridge structure could be combined with the good waveguiding characteristics and low leakage current of the buried heterostructure.

A need therefore exists for a self-aligned laser structure, which combines the advantages of the ridge structure and buried heterostructure while overcoming their shortcomings.

### SUMMARY OF THE INVENTION

According to a first aspect of the present invention, there is provided a self-aligned laser structure with an integral active and guiding layer. A continuous active region and a current blocking region forms a lateral waveguide. The blocking region has an index of refraction n1. The continuous guiding layer has an index of refraction n2, wherein n2 is greater than n1. The guiding layer and the blocking region are made of the same material. The blocking region has a real refractive index step forming a transverse optical mode, wherein the transverse laser mode is controlled by a change in doping level of the blocking region.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

The invention and its embodiments thereof will be described in conjunction with the accompanying drawings in which:

FIG. 1 is a diagram illustrating a ridge laser structure according to the prior art;

FIG. 2 is a diagram illustrating a buried heterostructure laser according to the prior art;

FIGS. 3a and 3b are schematic drawings of prior art Real Index Self-Aligned (RISA) structures which combine the good properties of the structures of FIGS. 1 and 2;

FIGS. 4a and 4b are structures of high power lasers according to a first and second embodiment of the present invention; and

FIGS. 5a, 5b and 5c are structures of high power lasers according to third and fourth embodiments of the present invention

### DETAILED DESCRIPTION OF THE PREFERRED EMBODIMENT

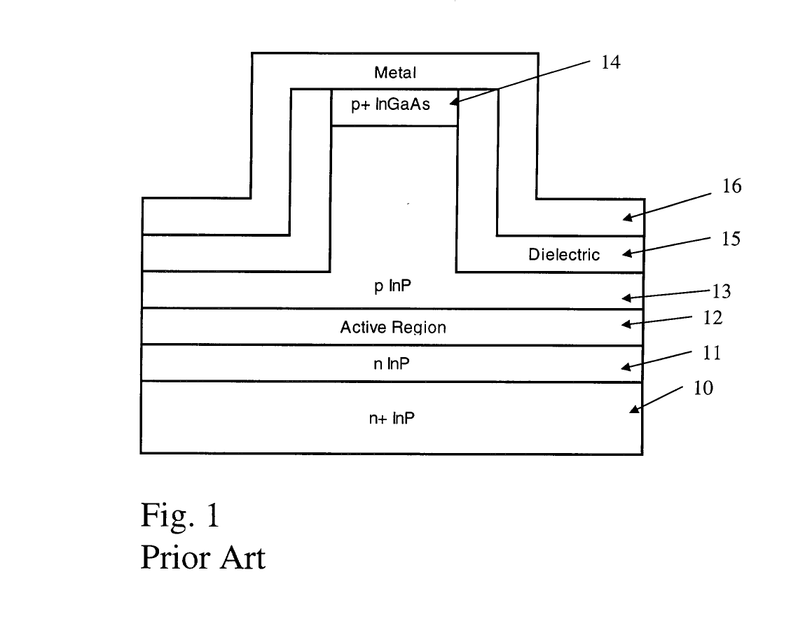

Referring now to FIG. 1, we have shown a schematic diagram illustrating a cross-section of a typical ridge laser structure.

Despite the simplicity of the ridge structure, the control of the lateral optical mode is complex. The ridge laser comprises an n+InP substrate 10, a layer of n−InP 11, an active region 12 and a p−InP layer forms the ridge section 13. A p+InGaAs layer 14 is then used as a contact layer to the ridge section 13. In this design both the air/semiconductor/air refractive index step and the strain in the dielectrics 15 and metal layers 16 contribute to the effective shape of the lateral optical mode. The advantages of this design are that only one growth step is required (two steps if a grating is included), the active region is continuous and the processing is simple which leads to a high yield device. The disadvantages are that the threshold current is high because the lateral leakage current is high. The contact area is small so that the heat dissipation is poor, and the optical mode control is hard to control, which might result in poor coupling efficiency.

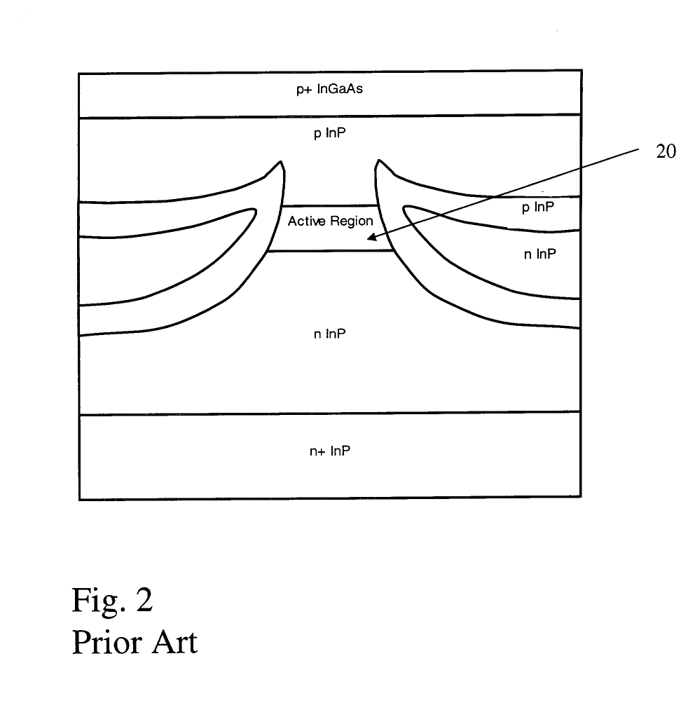

Referring now to FIG. 2, we have shown a cross-section of a Buried Heterostucture (BH) laser. In this design the lateral step of index of refraction that provides the lateral guiding of the optical mode is due to the etched active layer 20. The advantages of this structure are that the threshold current is low, because the lateral leakage current is low, the mode control is good and the contact area is large giving good heat dissipation. The disadvantages are that the structure requires three growth steps (four steps if a grating is included), which lower the yield and since the active region 20 has been etched, the non-radiative recombination can increase significantly to degrade the device performance and its reliability. Also, the high doping levels in the pn current blocking layers at a location of high optical density tend to increase the optical losses, which prevent the use of long cavities usually necessary to achieve high power.

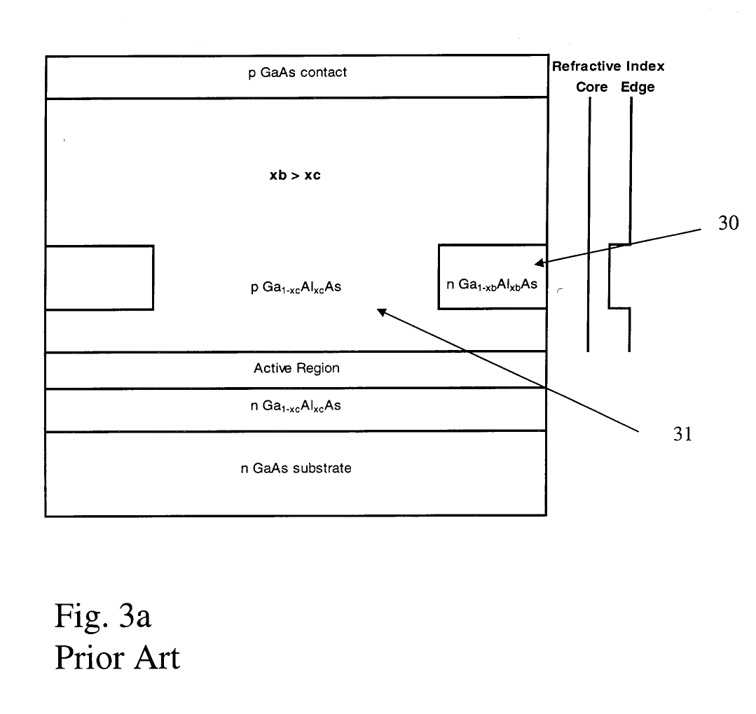

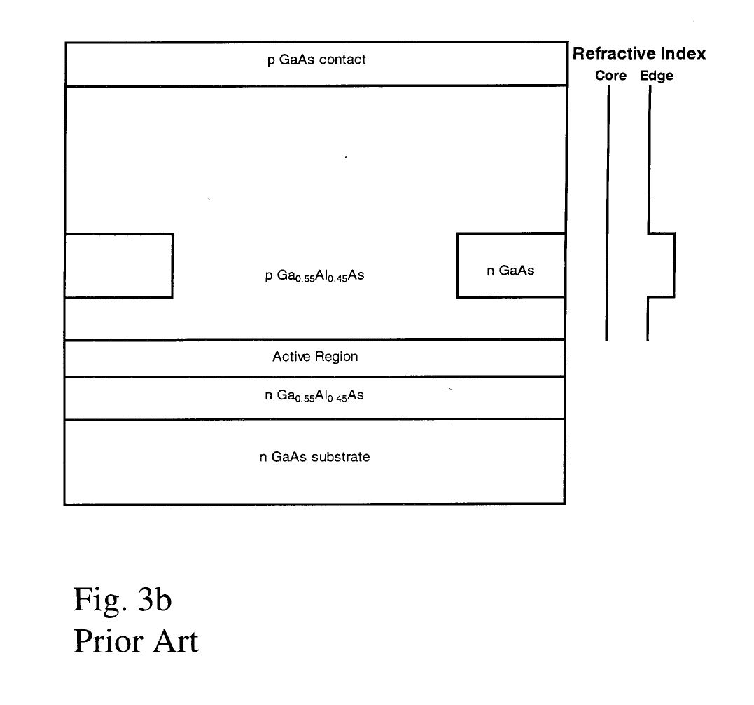

An attempt was made in combining the advantages from the ridge and the BH while limiting their disadvantages. This is shown in FIG. 3a. This cross-section represents a high power A1GaAs laser diode. The structure combines a real index guide with a self-aligned p-n-p blocking layer for current confinement. In this design the lateral index of refraction step that provides the lateral optical mode confinement is the difference in refractive index between A1xbGa1xbAs 30 and A1xcGa1-xcAs 31 with xb being larger than xc. Namely the guiding in this structure is provided by the incorporation of the A1xcGa1-xbAs 30 discontinuous layer with lower index of refraction. This layer 30 plays also the role of the current blocking layer.

Despite the improvements of the RISA structure described in FIG. 3a, this structure still has some drawbacks.. The RISA structure referred in FIG. 3a is made of a material system that does not operate well at wavelengths much beyond 980 nm.

Another alternative structure realized in the prior art is illustrated in Fig3b. Here material with lower band-gap is chosen for the blocking layers instead of being used for the cladding material. Lasers realized in this way experience lateral index anti-guiding and, depending on the wavelength of the mode, guiding through lateral absorption of the mode in the blocking layers is present. This results in unacceptably high optical losses, which degrade the device performance. Thus, a new structure with a material system capable of high output power operating at longer wavelengths, such as 1480 nm is required. As an example, a material system supporting operation at a longer wavelength like 1480 nm can be based on InP where InGaAsP compounds are used as a material with lower bandgap (i.e. higher index of refraction) and InP or InGaAsP compounds (with lower band-gap energy than InP) can be used where a lower index of refraction is required.

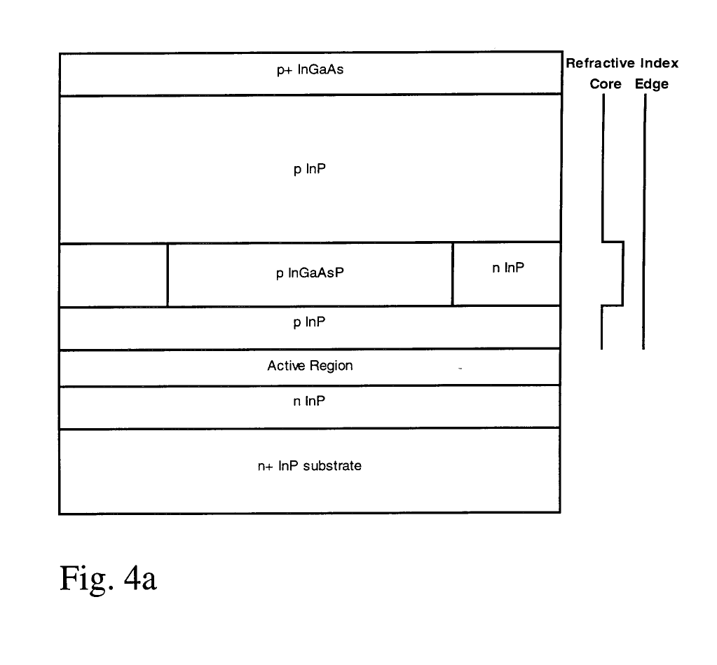

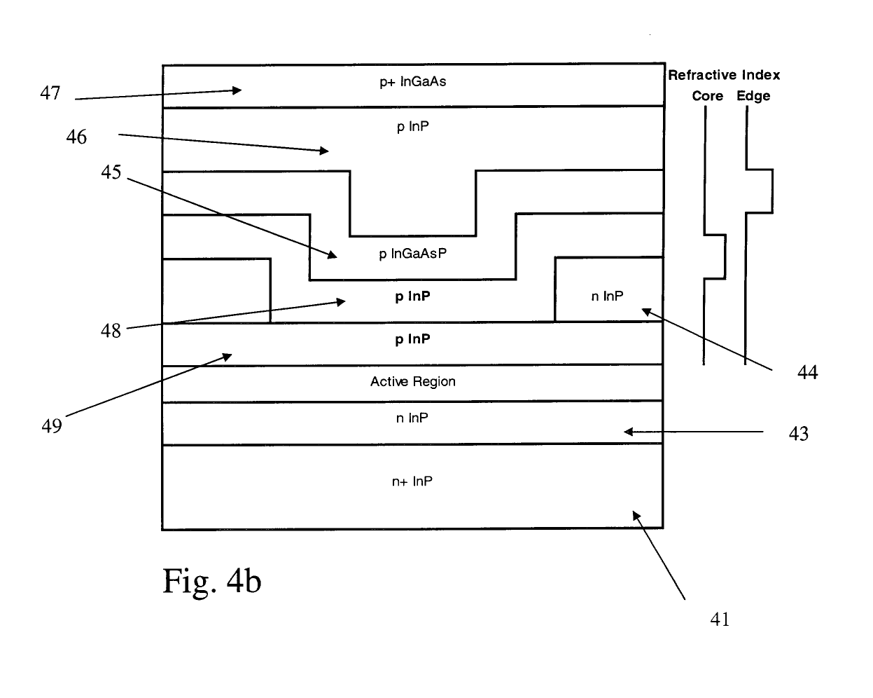

Referring now to FIGS. 4a and 4b, we have shown a first and second embodiment of the real refractive index-guided self-aligned laser structure of the present invention. Here the lateral index of refraction step that provides the lateral optical mode confinement is the difference between InP and InGaAsP (The refractive index of InGaAsP is higher than InP). In FIG. 4a, is shown a structure in InP where the lateral optical mode confinement is provided by the difference in refractive index between InP and InGaAsP weighted by the overlap of the optical mode with the named areas. In such a structure, InGaAsP is grown in the trench region while no material remains outside the trench. This can be achieved either by etching away the InGaAsP outside the trench or by selective overgrowth. In this case, the etch mask (preferrable a dielectric) could in principal be used for masking the area outside the trench. The trench would be partly or fully filled with the material of the waveguide. This requires no extra process step for masking but requires 3 growth steps instead of 2 for the structure of FIG. 4b. This is the case since after the growth of the waveguide layer in the trench one need to remove the dielectric and continue with the homogenous growth of the p-cladding. Another difficulty is that quaternary materials are difficult to control in composition especially if the surface is not planar, i.e. if they are grown in trenches. The embodiment of FIG. 4b achieves the same purpose as the structure of FIG. 4a but is a structure which is easier to manufacture and provides additional benefits. This structure comprises a n or n+InP region 41, a n−InP layer 43 and a n-doped blocking layer 44. The blocking layer 44 can consist of InP. A continuous p−InGaAsP guiding layer is shown at 45. It has an index of refraction greater than the index of refraction of the blocking layer 44. A P−InP region 46 is used to cover the guiding layer 45. A p contact 47 is then used to permit connection. In line with the teachings of this invention, a p−InP layer 48 can also be incorporated between the blocking layers 44 and the guiding layer 45. Similarly a p−InP layer 49 can be placed below the n−InP blocking layer 44 to adjust the lateral guiding strength independently of the lateral current confinement. A special feature and distinct advantage of this type of structure compared to the RISA structure is that the material surrounding the blocking layers and located especially in the core of the waveguide can be made of a material with the highest band-gap possible. In material systems with relatively low energy barriers between the active region and the cladding layers (exemplary but not limited to the system InP/InGaAsP) cladding layers with lower energy barriers lead to an unfavorable degradation in the device performance due to vertical heterobarrier carrier leakage. In RISA structures this cannot be achieved due to their inherent property, which requires that the guiding be provided by the discontinuous blocking layers. In a RISA structure the core of the structure needs to be of a material with a lower band-gap to obtain a contrast in the index of refraction between the high index core of the structure and the lower index obtained by the blocking layers.

This determines the mechanism by which the mode is guided. For the lateral direction the structure in FIG. 4b is guiding the mode by use of the guiding layer 45 instead of guiding the mode by use of the blocking layer as realized in FIG. 3a. This can most easily be seen if one looks at the lateral distribution of the refractive index at the position of the element providing the guiding. In FIG. 4b, the index is higher in the core of the structure and drops to a background value towards the edge of the structure. In FIG. 3a, for the RISA structure, the value in the core of the structure is the background value and drops to a lower value for the blocking layer providing the guiding. This means that in FIG. 4b the background value is the “low” refractive index while in FIG. 3a the background value is the “high” refractive index. The same holds for the realization in FIG. 4a.

A second feature and advantage of the invention is that the discontinuous p-n blocking layer can be made of a material with highest band-gap embedded into a material of complementary conductivity but also highest band-gap energy. This is favorable since it maximizes the voltage for breakdown of the p-n-blocking region. It is therefore again preferable to build both the discontinuous blocking layer and the surrounding cladding layers from the same high band-gap material.

A third feature and advantage of the invention is that it is made of a material system that is suitable for operation at longer wavelength beyond 980 nm wavelength.

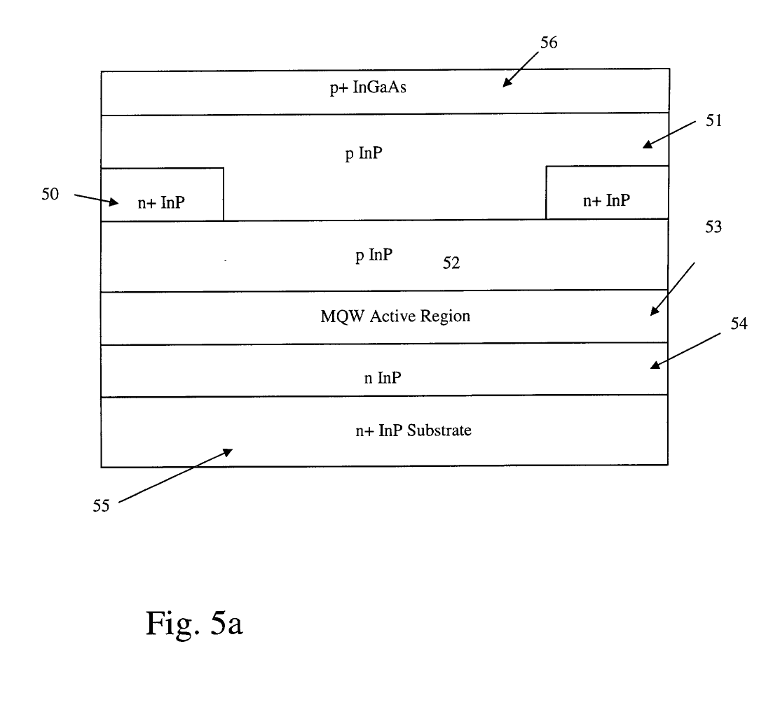

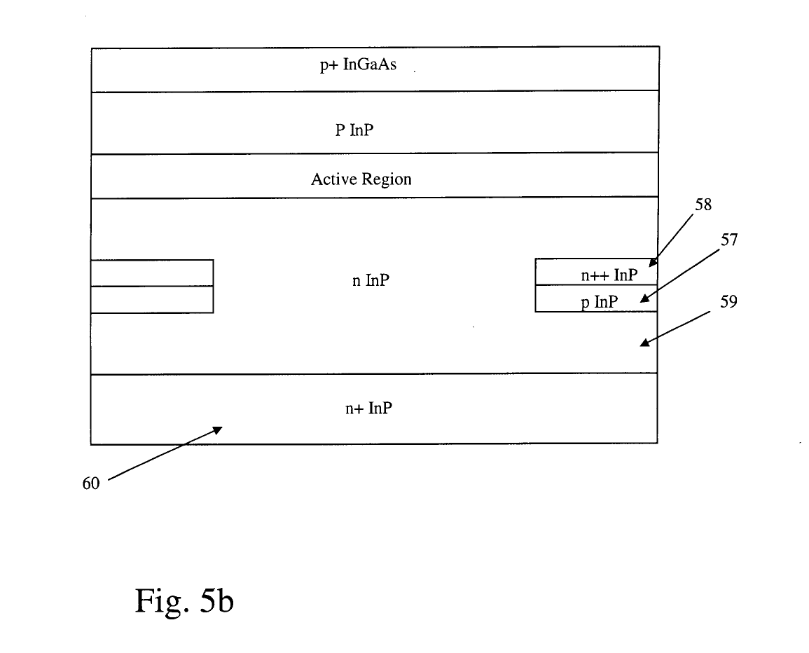

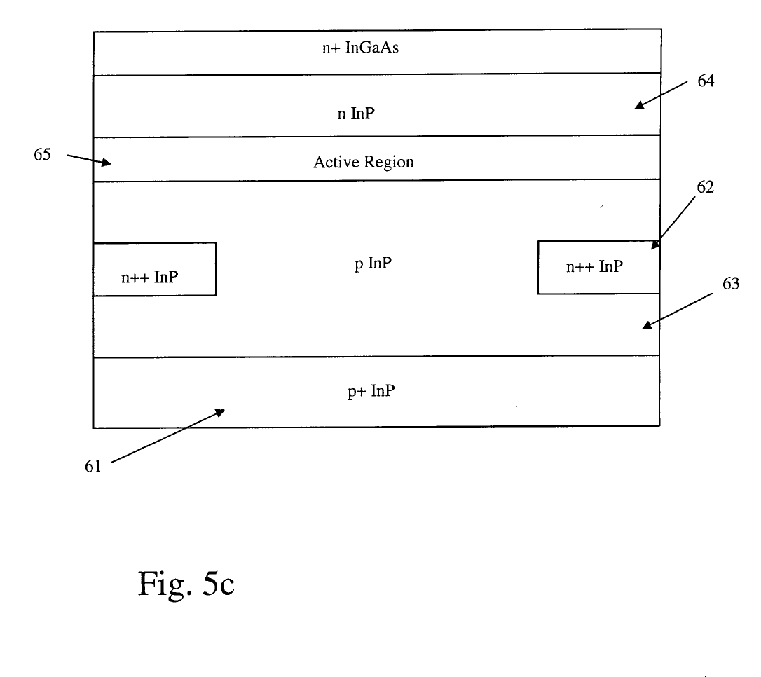

Referring now to FIG. 5a, we have shown a further embodiment of the present invention illustrating a dopant-induced real refractive index-guided self-aligned laser structure with integral current blocking layer. This structure is similar to the structures of FIGS. 4a and 4b, except that the blocking layer 50 in FIG. 5a is highly doped compared with the blocking layer 44 of FIGS. 4a and 4b. Similarly, the InGaAsP “dielectric step layer” 45 of FIG. 4b is replaced with a p−InP layer 51.

The blocking layer 50 can consist of n⁺-InP having a refractive index lower than the p−InP guide layer. The refractive index step between n⁺-InP @˜1×10¹⁹cm⁻³ and p−InP @˜1×10¹⁸ Cm⁻³ is ˜0.05, which is large enough to control a transverse optical mode. A p−InP region 52 is used to cover the active region 53. The structure also comprises a n InP layer 54 over the n+InP substrate 55. A p contact 56 is then used to permit connection.

A special feature and distinct advantage of this type of structure is that it requires two epitaxial steps (three steps if a grating is required), one less than the traditional BH. The first growth finishes with the n⁺-InP 50, and the second growth starts with p−InP 51 over the slotted wafer surface. In addition, the MQW active region 53 is continuous and has not been etched through as in the BH. The structure is self-aligned thus making manufacture simpler and the transverse mode is easier to control as it only depends on the thickness and doping level in n−InP blocking layer 50. Further, the regrowth of p−nP over an etched slot is more ready to planarise than InGaAsP. Similarly, it is much easier to control and reproduce the thickness and doping level of InP than it is to control the thickness, composition and doping level of InGaAsP, especially in an etched slot.

This is the first time that a transverse laser mode has been controlled by a change in doping level rather than a change in material composition. It is also the first time that an InP blocking layer has had a dual role where it acts as a blocking layer and as a mode control layer.

In the embodiment of FIG. 5b, the blocking layer is comprised of a p InP layer 57 covered by a layer of n+InP 58. The guiding layer 59 is made of n InP over an n substrate 60.

In FIG. 5c, the illustrated embodiment is shown on a p-substrate 61, with a n++ blocking layer 62 and a pInP guiding layer 63. A n−InP region 64 is used to cover the active region 65 and a n contact 66 is then used to permit connection.

It will be known to those knowledgeable in the art that various combinations of layer materials can be used to achieve the guiding and blocking layers wherein the index of refraction of the guiding layer is greater than the index of refraction of the blocking layer. Similarly, the type of conductivity of the materials used can be inverted and still offer the same characteristics. For example, the guiding and blocking layers can be made of GaN, InP, GaAs, etc.

In addition it is recognized that this invention can also be used for active regions consisting of a double-heterostructure active region as well as for single- (SQW) or multiple quantum well (MQW) active areas. In the preferred embodiment, the structure is realized preferably with a MQW active region.

It is also recognized that this invention can also incorporate one or more elements for wavelength stabilization of the device like DFB gratings.

We claim:

1. A self-aligned laser structure with an integral active and guiding layer, comprising:
a continuous active region and a current blocking regionforming a lateral waveguide, said blocking region having an index of refraction n1 and a continuous guiding layer having an index of refraction n2, wherein n2 is greater than n1, said guiding layer and said blocking region being made of the same material, said blocking region having a real refractive index step to form a transverse optical mode, wherein the transverse laser mode is controlled by a change in doping level of said blocking region..

2. A laser structure as defined in claim 1, wherein said active and current blocking regions are made of the same conductivity type.

3. A laser structure as defined in claim 2, wherein said guiding layer and said blocking region is made of GaN

4. A laser structure as defined in claim 2, wherein said material comprises InP, GaN or GaAs.

5. A laser structure as defined in claim 2, wherein n+InP is used as a blocking layer and a mode control layer

6. A laser structure as defined in claim 1, wherein wavelength selective grating areas are included.
